(19) United States
(12) Patent Application Publication
(10) Pub. No.: US 2013/0226516 A1
(43) Pub. Date: Aug. 29, 2013

(54) MAGNETIC FIELD INTENSITY CONVERSION DEVICE AND METHOD

(71) Applicant: Electronics And Telecommunications Research In, (US)

(72) Inventors: Sang Bong JEON, Daejeon (KR); Seung Keun PARK, Daejeon (KR); Sung Woong CHOI, Daejeon (KR)

(73) Assignee: ELECTRONICS AND TELECOMMUNICATIONS RESEARCH INSTITUTE, Daejeon (KR)

(21) Appl. No.: 13/666,092

(22) Filed: Nov. 1, 2012

(30) Foreign Application Priority Data
Feb. 27, 2012 (KR) 10-2012-0019955

(51) Int. Cl. G01R 33/02; G06F 15/00

(52) U.S. Cl. 702/158

(57) ABSTRACT

Disclosed is a magnetic field intensity conversion method in a magnetic field intensity conversion device configured to convert and output magnetic field intensity for each distance from a magnetic field source, and the method includes: receiving a reference distance and a target distance from the magnetic field source through an input unit; primarily comparing the reference distance with a critical value calculated in accordance with the wavelength of an electromagnetic wave, in a control unit; secondarily comparing the target distance with the critical distance, in the control unit; and calculating conversion magnetic field intensity by converting reference magnetic field intensity prescribed for the reference distance into magnetic field intensity at the target distance, on the basis of the comparing results in the primary comparing and the secondary comparing, in the control unit.

### CROSS-REFERENCES TO RELATED APPLICATIONS

The present application claims priority under 35 U.S.C 119(a) to Korean Application No. 10-2012-0019955, filed on Feb. 27, 2012, in the Korean Intellectual Property Office, which is incorporated herein by reference in its entirety set forth in full.

### BACKGROUND

Exemplary embodiments relate to a magnetic field intensity conversion device and a method, and more particularly, to a magnetic filed intensity conversion device configured to effectively check whether magnetic field intensity measured at a predetermined distance from a magnetic field source satisfies a standard, and a method thereof.

The related art of the present invention is disclosed in Japanese Unexamined Patent Publication No. 2000-304790 (published on Nov. 1, 2000).

Recently, an electromagnetic wave concentration space where intended electric waves and unintended electric waves of wireless devices all exist is formed in a ubiquitous space due to rapid development of electric and electronic devices. In particular, systems of which a wireless service such as AM broadcasting is influenced by radiated emission at a frequency band at 30 MHz or less, such as a wireless power transmitting device or a PDP TV are increasing. However, the radiated emission is considered now only for 30 MHz or more, so that it is necessary to establish measuring method and process for measuring and estimating radiated emission at a low frequency band.

It is required to increase the size of a measurement test place in order to measure magnetic field intensity of radiated emission at 30 MHz or less at a distance that satisfies a far-field condition from a magnetic field source, and accordingly, a burden in terms of cost increases. However, if a conversion method that can be applied to near-field and far-field conditions is proposed, magnetic field intensity for various measurement distances can be converted into standard limit value, so that it is possible to permit measurement test places having various sizes, including measurement distances 3 m, 5 m, and 10 m.

The conversion methods of magnetic field intensity of radiated emission at 30 MHz or more in the related art uses 10.5 dB in conversion from 10 m into 3 m by applying a far-field condition, but there is a limit in applying the method of the related art because near-field and far-field conditions are included for the frequency band at 30 MHz or less. In order to overcome the limit of the related art, it is necessary to apply conversion of magnetic field intensity for radiated emission in a region including near-field/far-field conditions by finding out and analyzing a cross-over point frequency for the direction in which the maximum emission is generated, by finding out the radiation characteristics of a magnetic field source at a low frequency band including near-field and far-field conditions.

### SUMMARY

An exemplary embodiment of the present invention is directed to provide a magnetic field conversion and a method thereof, which are configured to effectively check whether magnetic field intensity measured at a predetermined distance from a magnetic field source satisfies a standard, by converting and providing reference magnetic field intensity for a reference distance from a magnetic field source which is prescribed in a standard, in magnetic filed intensity for a predetermined target distance.

An exemplary embodiment of the present invention relates to a magnetic field intensity conversion method in a magnetic field intensity conversion device configured to convert and output magnetic field intensity for each distance from a magnetic field source, and the method includes: receiving a reference distance and a target distance from the magnetic field source through an input unit; primarily comparing the reference distance with a critical value calculated in accordance with the wavelength of an electromagnetic wave, in a control unit; secondarily comparing the target distance with the critical distance, in the control unit; and calculating conversion magnetic field intensity by converting reference magnetic field intensity prescribed for the reference distance into magnetic field intensity at the target distance, on the basis of the comparing results in the primary comparing and the secondary comparing, in the control unit.

The method may further include calculating a conversion coefficient between the reference magnetic field intensity at the reference distance and the conversion magnetic field intensity at the target distance, on the basis of the calculated conversion magnetic field intensity at the target distance, in the control unit.

The calculating may include: calculating magnetic field dipole moment on the basis of reference magnetic field intensity stored in advance which corresponds to the reference distance, in the control unit; and calculating conversion magnetic field intensity at the target distance on the basis of the magnetic field dipole moment, in the control unit.

When the reference distance is not more than the critical value,

$$m = {H}_{Ref} [ \frac{λ {r}^{3}}{\sqrt{{( λ / 2 π )}^{2} + {r}^{2}}} ] [ {Am}^{2} ]$$

and

$${H}_{Mea} = \frac{m}{2 π} [ \frac{\sqrt{{( λ / 2 π )}^{2} + {d}^{2}}}{( λ / 2 π ) {d}^{3}} ] [ A \text{/} m ]$$

when the target distance is not more than the critical value, and

$$m = {H}_{Ref} [ \frac{λ {r}^{3}}{\sqrt{{( λ / 2 π )}^{2} + {r}^{2}}} ] [ {Am}^{2} ]$$

and

$${H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A / m ]$$

when the target distance exceeds the critical value (where m is the magnetic dipole moment, H_{Ref} is the reference magnetic filed strength, λ is a wavelength, r is the reference distance, d is the target distance, and H_{Mea} is a conversion magnetic field intensity at the target distance).

When the reference distance exceeds the critical value,

$$m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ]$$

and

$${H}_{Mea} = \frac{m}{2 π} [ \frac{\sqrt{{( λ / 2 π )}^{2} + {d}^{2}}}{( λ / 2 π ) {d}^{3}} ] [ A / m ]$$

when the target distance is not more than the critical value, and

$$m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ]$$

and

$${H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A / m ]$$

when the target distance exceeds the critical value (where m is the magnetic dipole moment, H_{Ref} is the reference magnetic filed strength, λ is a wavelength, r is the reference distance, d is the target distance, and H_{Mea} is a conversion magnetic field intensity at the target distance).

The critical value may be calculated from 2.354*λ/2π and λ may be the wave length.

Another exemplary embodiment of the present invention provides a magnetic field intensity conversion device configured to convert and output magnetic field intensity for each distance from a magnetic field source, and includes: an input unit configured to receive a reference distance and a target distance from the magnetic field source; and a control unit configured to primarily compare the reference distance with a critical value calculated in accordance with the wavelength of an electromagnetic wave, secondarily compare the target distance with the critical distance; and calculate conversion magnetic field intensity by converting reference magnetic field intensity prescribed for the reference distance into magnetic field intensity at the target distance, on the basis of the primary and secondary comparing results.

The control unit may further calculate a conversion coefficient between the reference magnetic field intensity at the reference distance and the conversion magnetic field intensity at the target distance, on the basis of the calculated conversion magnetic field intensity at the target distance.

When calculating the conversion magnetic field intensity at the target distance, the control unit may calculate magnetic field dipole moment on the basis of reference magnetic field intensity stored in advance in a memory which corresponds to the reference distance, and calculate conversion magnetic field intensity at the target distance on the basis of the magnetic field dipole moment.

When the reference distance is not more than the critical value,

$$m = {H}_{Ref} [ \frac{λ {r}^{3}}{\sqrt{{( λ / 2 π )}^{2} + {r}^{2}}} ] [ {Am}^{2} ]$$

and

$${H}_{Mea} = \frac{m}{2 π} [ \frac{\sqrt{{( λ / 2 π )}^{2} + {d}^{2}}}{( λ / 2 π ) {d}^{3}} ] [ A / m ]$$

when the target distance is not more than the critical value, and

$$m = {H}_{Ref} [ \frac{λ {r}^{3}}{\sqrt{{( λ / 2 π )}^{2} + {r}^{2}}} ] [ {Am}^{2} ]$$

and

$${H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A / m ]$$

when the target distance exceeds the critical value (where m is the magnetic dipole moment, H_{Ref} is the reference magnetic filed strength, λ is a wavelength, r is the reference distance, d is the target distance, and H_{Mea} is a conversion magnetic field intensity at the target distance).

When the reference distance exceeds the critical value,

$$m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ]$$

and

$${H}_{Mea} = \frac{m}{2 π} [ \frac{\sqrt{{( λ / 2 π )}^{2} + {d}^{2}}}{( λ / 2 π ) {d}^{3}} ] [ A / m ]$$

when the target distance is not more than the critical value, and

$$m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ]$$

and

$${H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A / m ]$$

when the target distance exceeds the critical value (where m is the magnetic dipole moment, H_{Ref} is the reference magnetic filed strength, λ is a wavelength, r is the reference distance, d is the target distance, and H_{Mea} is a conversion magnetic field intensity at the target distance).

The critical value may be calculated from 2.354*λ/2π may be the wave length.

The magnetic field intensity conversion device and the method thereof according to the present exemplary embodiment make it possible to effectively check whether magnetic field intensity measured at a predetermined distance from a magnetic field source satisfies a standard, by converting and providing the reference magnetic field intensity for the reference distance from a magnetic field source prescribed in the standard into the magnetic field intensity for a predetermined specific target distance.

### BRIEF DESCRIPTION OF THE DRAWINGS

The above and other aspects, features and other advantages will be more clearly understood from the following detailed description taken in conjunction with the accompanying drawings, in which:

FIG. 1 is a conceptual diagram illustrating a magnetic dipole and the radiation direction in a loop antenna;

FIG. 2A is a diagram illustrating the frequency-magnetic intensity relationship in a coaxial direction and a coplanar direction at a reference distance of 3 m;

FIG. 2B is a diagram illustrating the frequency-magnetic intensity relationship in a coaxial direction and a coplanar direction at a reference distance of 10 m;

FIG. 2C is a diagram illustrating the frequency-magnetic intensity relationship in a coaxial direction and a coplanar direction at a reference distance of 30 m;

FIG. 3 is a brief diagram illustrating reference magnetic field intensity at a point spaced at a reference distance from a magnetic field source and magnetic field intensity at a point spaced at a predetermined target distance from the magnetic field source;

FIG. 4 is a diagram illustrating the configuration of a magnetic field conversion device in accordance with an exemplary embodiment of the present invention;

FIG. 5 is a flowchart illustrating a magnetic field conversion method in accordance with an exemplary embodiment of the present invention;

FIG. 6A is a diagram illustrating a change in conversion coefficient for calculating magnetic intensity at a target distance of 3 m; and

FIG. 6B is a diagram illustrating a change in conversion coefficient for calculating magnetic intensity at a target distance of 30 m.

### DESCRIPTION OF SPECIFIC EMBODIMENTS

Hereinafter, exemplary embodiments of the present invention will be described in detail with reference to the accompanying drawings so that those skilled in the art may easily practice the present invention. However, the present invention may be modified in various different ways and is not limited to the exemplary embodiments provided in the present description. In the accompanying drawings, portions unrelated to the description will be omitted in order to obviously describe the present invention, and similar reference numerals will be used to describe similar portions throughout the present specification.

Through the present specification, unless explicitly described otherwise, “comprising” any components will be understood to imply the inclusion of other components rather than the exclusion of any other components.

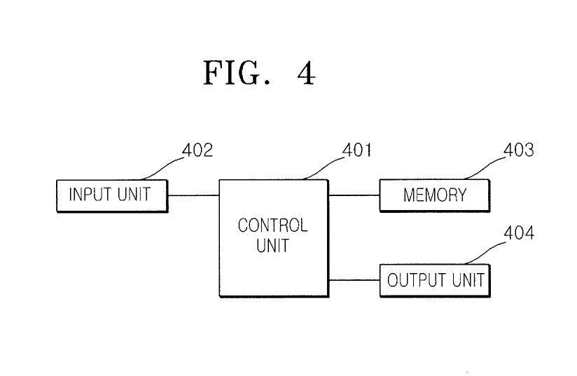

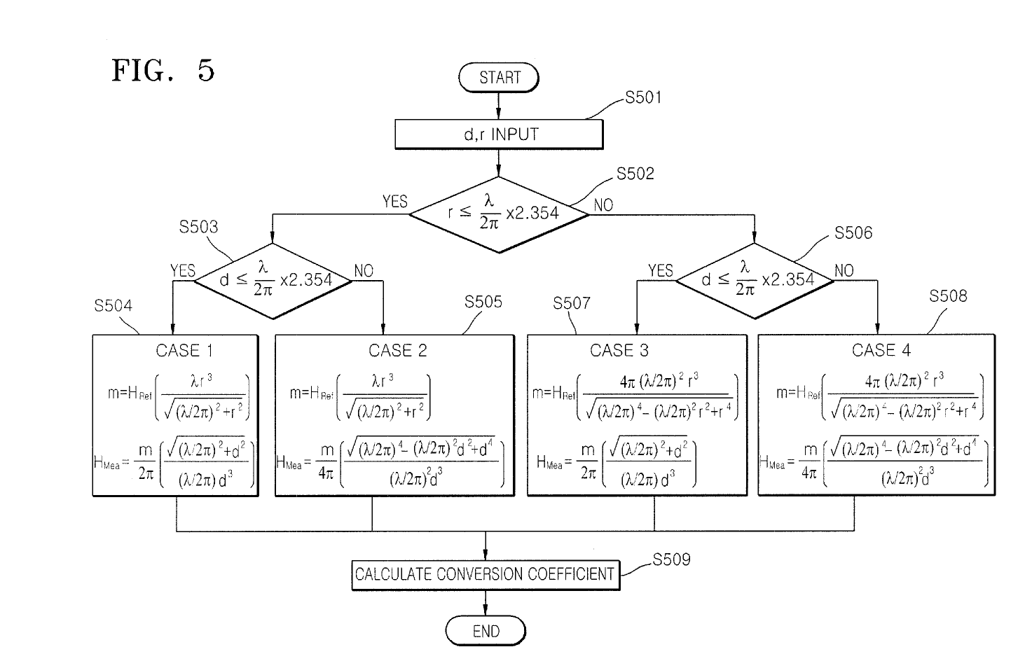

FIG. 4 is a diagram illustrating the configuration of a magnetic field conversion device in accordance with an exemplary embodiment of the present invention and FIG. 5 is a flowchart illustrating a magnetic field conversion method in accordance with an exemplary embodiment of the present invention, and the present invention will be described hereafter with reference to the figures.

A magnetic field intensity conversion device according to an exemplary embodiment of the present invention, as illustrated in FIGS. 4 and 5, is a magnetic field intensity conversion device configured toe convert and output magnetic field intensity for each distance from a magnetic field source, and includes an input unit 402 configured to receive a reference distance r and a target distance d from the magnetic field source, and a control unit 401 configured to preliminarily compare the reference distance r with a critical value calculated in accordance with the wavelength of an electromagnetic wave, secondarily compare the target distance r with the critical value, and calculate conversion magnetic field intensity by converting reference magnetic field intensity prescribed for the reference distance r into magnetic field intensity at the target distance d on the basis of the preliminary and secondary comparing results.

The control unit 401 may further calculate a conversion coefficient between the reference magnetic field intensity at the reference distance r and the conversion magnetic field intensity at the target distance r, on the basis of the conversion magnetic field intensity at the target distance d. When calculating the conversion magnetic field intensity at the target distance d, the control unit 401 may calculate a magnetic field dipole moment on the basis of the reference magnetic field intensity stored in advance in a memory 403 which correspond to the reference distance r, and calculate the conversion magnetic field intensity at the target distance d on the basis of the magnetic field dipole moment.

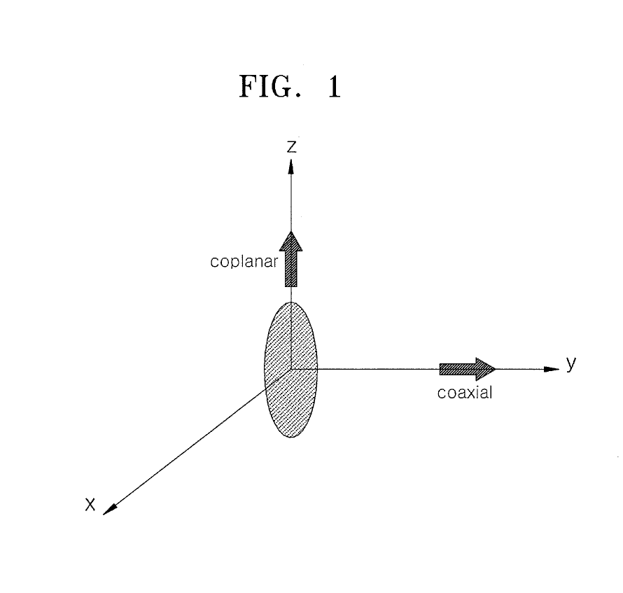

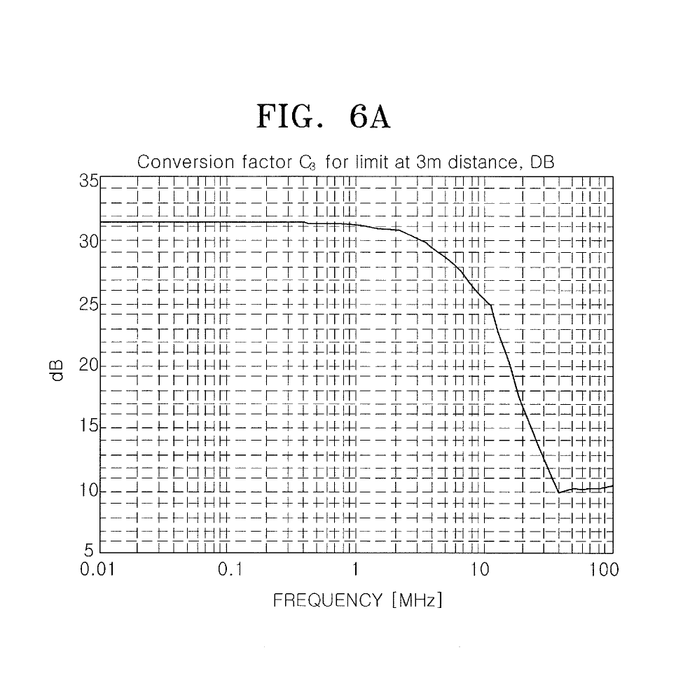

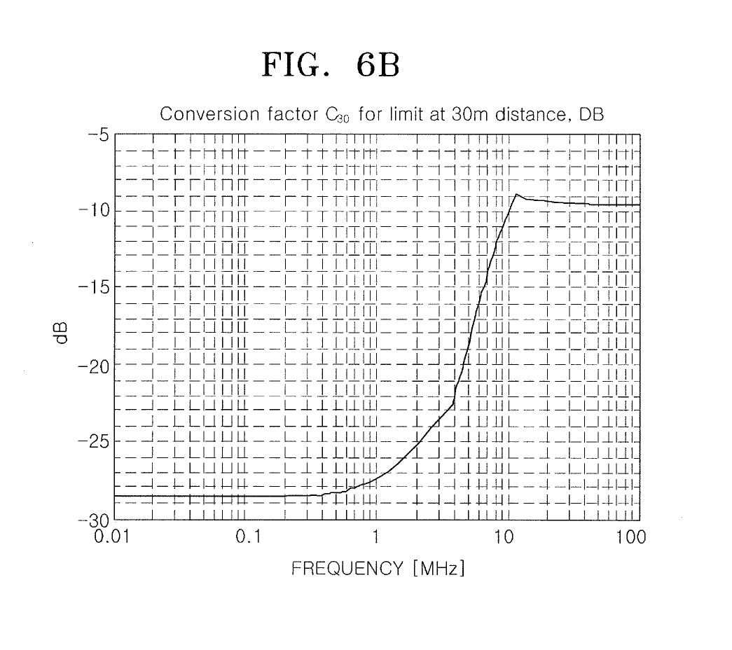

The movement and operation of the present exemplary embodiment having the configuration described above are described in detail with reference to FIGS. 1 to 6.

As illustrated in FIG. 5, the magnetic field intensity conversion device receives a reference distance r and a target distance d from a magnetic field source (not shown) through the input unit 402 (S501).

Next, the control unit 410 compares the reference distance r with a predetermined critical value calculated in accordance with the wavelength λ of an electromagnetic wave (S502).

FIG. 1 is a conceptual diagram illustrating a magnetic dipole and the radiation direction in a loop antenna, and as illustrated in FIG. 1, radiation of the loop antenna is defined in a coaxial direction and a coplanar direction by magnetic field dipole radiation. The magnetic field dipole moments in two directions are calculated in the following Equations 1 and 2.

$$\begin{matrix}m = \vert H \vert [ \frac{λ {r}^{3}}{\sqrt{{( λ / 2 π )}^{2} + {r}^{2}}} ] & [ Equation 1 ] \\ m = \vert H \vert [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] & [ Equation 2 ]\end{matrix}$$

(where H is magnetic field intensity, λ is a wavelength, and r is a reference distance)

In the Equations, Equation 1 expresses moment in the coaxial direction and Equation 2 expresses moment in the coplanar direction.

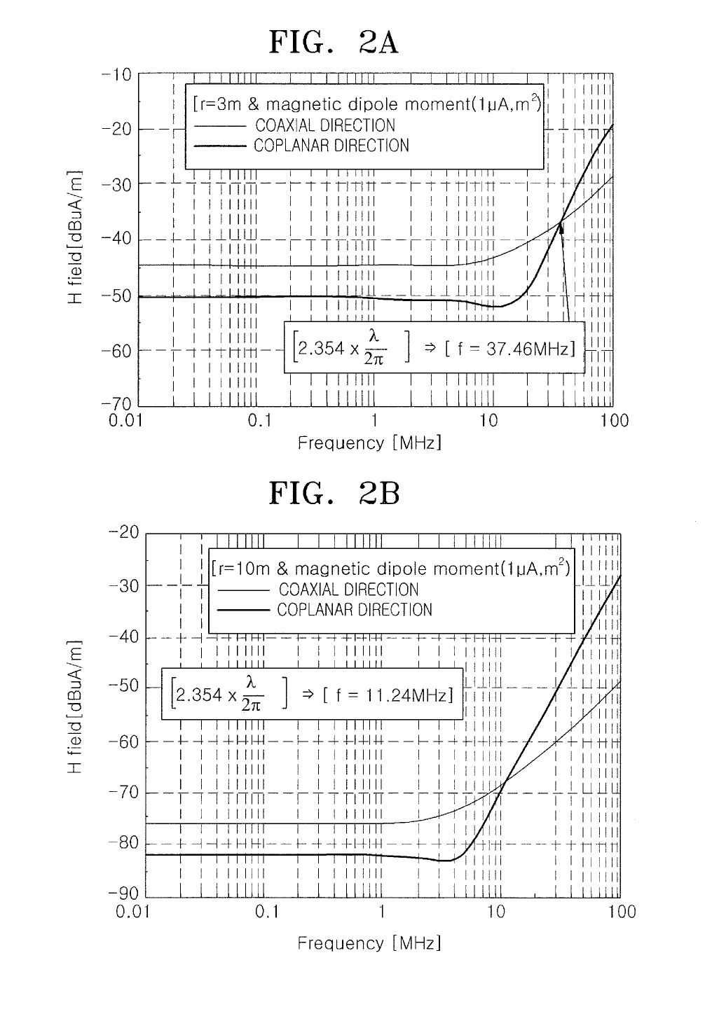

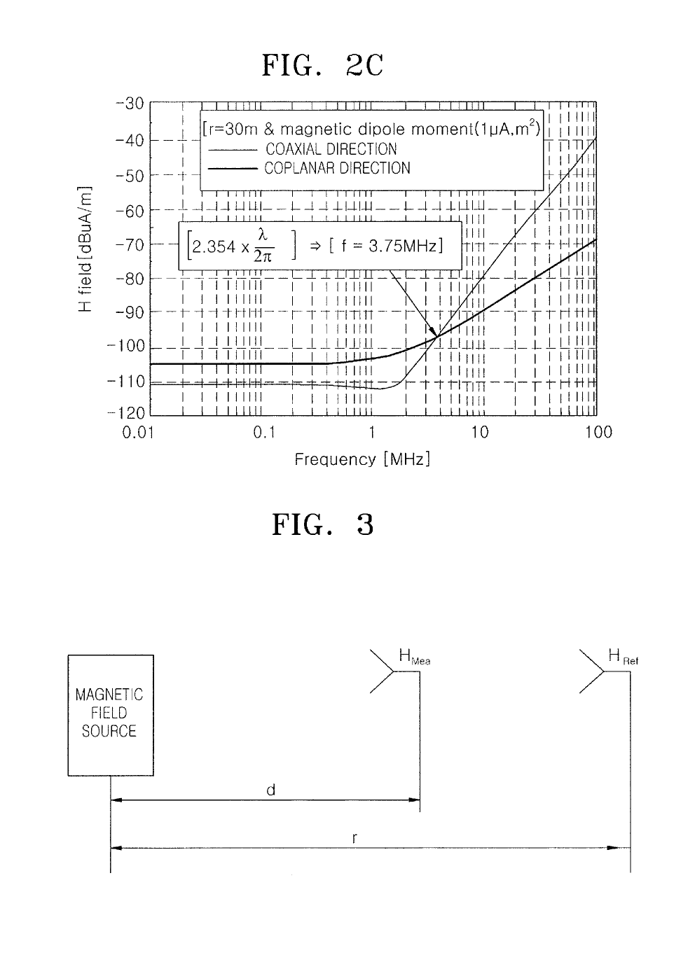

Magnetic field intensity was calculated, using Equation (1) and Equation (2) to find out the direction of the maximum radiation from the magnetic field moment. FIGS. 2A and 2B are diagrams illustrating the frequency-magnetic field intensity in the coaxial direction and the coplanar direction at reference distances 3 m, 10 m, and 30 m, when the magnetic field dipole moment is 1 [μA·m²]. It can be seen from FIGS. 2A and 2B that the direction in which the magnetic field moment is maximally radiated changes at the frequency of 2.354*λ/2π. In other words, the magnetic field intensity radiated in the coaxial direction is the maximum at a frequency of 2.354*λ/2π or less, and the magnetic field intensity radiated in the coplanar direction is the maximum at a frequency of 2.354*λ/2π or more.

FIG. 3 is a brief diagram illustrating reference magnetic field intensity H_{Ref} at a point spaced at the reference distance from a magnetic field source and conversion magnetic field intensity H_{Mea} at a point spaced at a predetermined target distance d.

EMC rules established by IEC CISPR committee prescribes that the reference magnetic field intensity should be a predetermined level or less at a position spaced at a predetermined reference distance from a magnetic field source. For example, predetermined magnetic field intensity is prescribed for a position spaced at a reference distance of 10 m from a magnetic field source, and when the magnetic field intensity is not more than the reference magnetic field, it passes, but it exceeds the reference magnetic field intensity, it fails. The standard values are prescribed only for specific reference distances, it is very important to convert the standard values into conversion magnetic field intensity at desired target distances d.

However, it is not easy to convert the reference magnetic field intensity at a reference distance r into magnetic field intensity at a measured distance, that is, a target distance d, because the boundary between a near-field and a far-field changes in accordance with the frequency and the distance. The types of magnetic field intensity conversion are classified as in Table 1, using the results of FIGS. 2A to 2C and the following steps after step S502 of FIG. 5 are performed, in the present exemplary embodiment, to calculate conversion magnetic field intensity.

TABLE 1

| Category | Reference Distance (r) | Target Distance (d) |
|---|---|---|
| Case 1 | $\frac{λ}{2 π} \times 2.354 \geq r$ | $\frac{λ}{2 π} \times 2.354 \geq d$ |
| Case 2 | $\frac{λ}{2 π} \times 2.354 \geq r$ | $\frac{λ}{2 π} \times 2.354 \geq d$ |
| Case 3 | $\frac{λ}{2 π} \times 2.354 \geq r$ | $\frac{λ}{2 π} \times 2.354 \geq d$ |
| Case 4 | $\frac{λ}{2 π} \times 2.354 \geq r$ | $\frac{λ}{2 π} \times 2.354 \geq d$ |

As the result of comparing in step S502, when the reference distance r is not more than the critical value calculated in accordance with the wavelength λ of the electromagnetic wave, the control unit 401 compares the target distance d with the critical value (S503). The critical value is obtained from 2.354*λ/2π.

As the result of comparing in step S503, when the target distance d is not more than the critical value, the conversion magnetic field intensity is calculated by converting the reference magnetic field intensity prescribed for the reference distance r into the magnetic field at the target distance d, in which the conversion magnetic field intensity is calculated from the following Equations 3 and 4 (S504).

$$\begin{matrix}m = {H}_{Ref} [ \frac{λ {r}^{3}}{\sqrt{{( λ / 2 π )}^{2} + {r}^{2}}} ] [ {Am}^{2} ] & [ Equation 3 ] \\ {H}_{Mea} = \frac{m}{2 π} [ \frac{\sqrt{{( λ / 2 π )}^{2} + {d}^{2}}}{( λ / 2 π ) {d}^{3}} ] [ A / m ] & [ Equation 4 ]\end{matrix}$$

(where m is magnetic dipole moment, H_{Ref} is reference magnetic filed strength, λ is a wavelength, r is a reference distance, d is a target distance, and H_{Mea} is a conversion magnetic field intensity at the target distance, which are the same in the following).

That is, in this case, both the reference distance r and the target distance d are not more than the critical value, the magnetic field intensity radiated in the coaxial direction is superior, so that the control unit 401 calculates the conversion magnetic field intensity by converting the reference magnetic field intensity prescribed for the reference distance r into the magnetic field intensity at the target distance d, from Equations 3 and 4. The control unit 401 calculates the magnetic dipole moment m in accordance with Equation 3, using the reference magnetic field intensity H_{Ref} stored in advance in the memory 403 which corresponds to the reference distance r, from Equation 4, and calculates the magnetic field intensity H_{Mea} at the target distance d from Equation 4, using the magnetic field dipole moment m.

Meanwhile, as the result of comparing in step S503, when the target distance d exceeds the critical value, the conversion magnetic field intensity is calculated by converting the reference magnetic field intensity prescribed for the reference distance r into the magnetic field at the target distance d, in which the conversion magnetic field intensity is calculated from the following Equations 5 and 6 (S505).

$$\begin{matrix}m = {H}_{Ref} [ \frac{λ {r}^{3}}{\sqrt{{( λ / 2 π )}^{2} + {r}^{2}}} ] [ {Am}^{2} ] & [ Equation 5 ] \\ {H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A / m ] & [ Equation 6 ]\end{matrix}$$

That is, in this case, since the reference distance r is not more than the critical value and the target distance d exceeds the critical value, Equation 1 relating to the coaxial direction is taken for the reference numeral r and Equation 2 relating to coplanar direction is taken for the target distance d. Therefore, the control unit 401 calculates the conversion magnetic field intensity by converting the reference magnetic field intensity prescribed for the reference distance r into the magnetic field intensity at the target distance d, from Equations 5 and 6. The control unit 401 calculates the magnetic dipole moment m in accordance with Equation 5, using the reference magnetic field intensity H_{Ref} stored in advance in the memory 403 which corresponds to the reference distance r, from Equation 5, and calculates the magnetic field intensity H_{Mea} at the target distance d from Equation 6, using the magnetic field dipole moment m.

Meanwhile, as the result of comparing in step S502, when the reference distance r exceeds the critical value calculated in accordance with the wavelength λ of the electromagnetic wave, the control unit 401 compares the target distance d with the critical value (S506).

As the result of comparing in step S506, when the target distance d is not more than the critical value, the conversion magnetic field intensity is calculated by converting the reference magnetic field intensity prescribed for the reference distance r into the magnetic field at the target distance d, in which the conversion magnetic field intensity is calculated from the following Equations 7 and 8 (S507).

$$\begin{matrix}m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ] & [ Equation 7 ] \\ {H}_{Mea} = \frac{m}{2 π} [ \frac{\sqrt{{( λ / 2 π )}^{2} + {d}^{2}}}{( λ / 2 π ) {d}^{3}} ] [ A / m ] & [ Equation 8 ]\end{matrix}$$

That is, in this case, since the reference distance r exceeds the critical value and the target distance d is not more than the critical value, Equation 2 relating to the coplanar direction is taken for the reference numeral r and Equation 1 relating to coaxial direction is taken for the target distance d. Therefore, the control unit 401 calculates the conversion magnetic field intensity by converting the reference magnetic field intensity prescribed for the reference distance r into the magnetic field intensity at the target distance d, from Equations 7 and 8. The control unit 401 calculates the magnetic dipole moment m in accordance with Equation 7, using the reference magnetic field intensity H_{Ref}, from Equation 7, and calculates the magnetic field intensity H_{Mea} at the target distance d from Equation 8, using the magnetic field dipole moment m.

Meanwhile, as the result of comparing in step S506, when the target distance d exceeds the critical value, the conversion magnetic field intensity is calculated by converting the reference magnetic field intensity prescribed for the reference distance r into the magnetic field at the target distance d, in which the conversion magnetic field intensity is calculated from the following Equations 9 and 10 (S508).

$$\begin{matrix}m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ] & [ Equation 9 ] \\ {H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A / m ] & [ Equation 10 ]\end{matrix}$$

That is, in this case, both the reference distance r and the target distance d exceed the critical value, the magnetic field intensity radiated in the coplanar direction is superior, so that the control unit 401 calculates the conversion magnetic field intensity by converting the reference magnetic field intensity prescribed for the reference distance r into the magnetic field intensity at the target distance d, in accordance with Equations 9 and 10. The control unit 401 calculates the magnetic dipole moment m in accordance with Equation 9, using the reference magnetic field intensity H_{Ref}, from Equation 7, and calculates the magnetic field intensity H_{Mea} at the target distance d from Equation 10, using the magnetic field dipole moment m.

Next, the control unit 401 calculates the conversion coefficient between the reference magnetic field intensity at the reference distance r and the conversion magnetic field intensity at the target distance d, on the basis of the calculated conversion magnetic field intensity at the target distance d (S509). For example, when the reference distance r is 10 m and the target distance d, which is a measured distance, is 3 m and 30 m, it is possible to obtain the conversion coefficients C₃, C₃₀ for each distance, and it is possible to convert the reference magnetic field intensity at 10 m into the conversion magnetic field intensity by adding the conversion coefficients to the reference magnetic field intensity, as in Equations 11 and 12.

H₃ₘ=H₁₀ₘαC₃ [Equation 11]

H₃₀ₘ=H₁₀ₘ+C₃₀ [Equation 12]

(where H₁₀ₘ is a reference magnetic field intensity at 10 m, H₃ₘ is conversion magnetic field intensity at 3 m, H₃₀ₘ is conversion magnetic field intensity at 30 m, and C₃ and C₃₀ conversion coefficients)

The conversion magnetic field intensity calculated through the processes described above can be provided for a user through the output unit 404 such as a display window.

Meanwhile, although the reference distance r is compared first with the critical value and then the target distance d is compared with the critical value in the present exemplary embodiment, the order may be changed and the comparing steps may be simultaneously performed, and the present invention includes all those cases.

As described above, the magnetic field intensity conversion device and the method thereof according to the present exemplary embodiment make it possible to effectively check whether magnetic field intensity measured at a predetermined distance from a magnetic field source satisfies a standard, by converting and providing the reference magnetic field intensity for the reference distance from a magnetic field source prescribed in the standard into the magnetic field intensity for a predetermined specific target distance.

Although an exemplary embodiment of the present invention was described in detail above, the scope of the present invention is not limited thereto and various changes and modifications by those skilled in the art using the basic concept of the present invention which is defined in the following claims are included in the scope of the present invention.

What is claimed is:

1. A magnetic field intensity conversion method in a magnetic field intensity conversion device configured to convert and output magnetic field intensity for each distance from a magnetic field source, the method comprising:
receiving a reference distance and a target distance from the magnetic field source through an input unit;
primarily comparing the reference distance with a critical value calculated in accordance with the wavelength of an electromagnetic wave, in a control unit;
secondarily comparing the target distance with the critical distance, in the control unit; and
calculating conversion magnetic field intensity by converting reference magnetic field intensity prescribed for the reference distance into magnetic field intensity at the target distance, based on the comparing results in the primary comparing and the secondary comparing, in the control unit.

2. The method of claim 1, further comprising calculating a conversion coefficient between the reference magnetic field intensity at the reference distance and the conversion magnetic field intensity at the target distance, based on the calculated conversion magnetic field intensity at the target distance, in the control unit.

3. The method of claim 1, wherein the calculating includes:
calculating magnetic field dipole moment based on reference magnetic field intensity stored in advance which corresponds to the reference distance, in the control unit; and
calculating conversion magnetic field intensity at the target distance based on the magnetic field dipole moment, in the control unit.

4. The method of claim 3, wherein when the reference distance is not more than the critical value,
$$m = {H}_{Ref} [ \frac{λ {r}^{3}}{\sqrt{{( λ / 2 π )}^{2} + {r}^{2}}} ] [ {Am}^{2} ]$$
and
$${H}_{Mea} = \frac{m}{2 π} [ \frac{\sqrt{{( λ / 2 π )}^{2} + {d}^{2}}}{( λ / 2 π ) {d}^{3}} ] [ A / m ]$$
when the target distance is not more than the critical value, and
$$m = {H}_{ref} [ \frac{λ {r}^{3}}{\sqrt{{( λ / 2 π )}^{2} + {r}^{2}}} ] [ {Am}^{2} ]$$
and
$${H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A \text{/} m ]$$
when the target distance exceeds the critical value (where m is the magnetic dipole moment, H_{Ref} is the reference magnetic field strength, λ is a wavelength, r is the reference distance, d is the target distance, and H_{Mea} is a conversion magnetic field intensity at the target distance).

5. The method of claim 3, wherein when the reference distance exceeds the critical value,
$$m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ]$$
and
$${H}_{Mea} = \frac{m}{2 π} [ \frac{\sqrt{{( λ / 2 π )}^{2} + {d}^{2}}}{( λ / 2 π ) {d}^{3}} ] [ A \text{/} m ]$$
when the target distance is not more than the critical value, and
$$m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ]$$
and
$${H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A \text{/} m ]$$
when the target distance exceeds the critical value (where m is the magnetic dipole moment, H_{Ref} is the reference magnetic field strength, λ is a wavelength, r is the reference distance, d is the target distance, and H_{Mea} is a conversion magnetic field intensity at the target distance).

6. The method of claim 1, wherein the critical value is calculated from 2.354*λ/2π and λ is the wave length.

7. A magnetic field intensity conversion device configured to convert and output magnetic field intensity for each distance from a magnetic field source, the device comprising:
an input unit configured to receive a reference distance and a target distance from the magnetic field source; and
a control unit configured to primarily compare the reference distance with a critical value calculated in accordance with the wavelength of an electromagnetic wave, secondarily compare the target distance with the critical distance; and calculate conversion magnetic field intensity by converting reference magnetic field intensity prescribed for the reference distance into magnetic field intensity at the target distance, based on the primary and secondary comparing results.

8. The device of claim 7, wherein the control unit further calculates a conversion coefficient between the reference magnetic field intensity at the reference distance and the conversion magnetic field intensity at the target distance, based on the calculated conversion magnetic field intensity at the target distance.

9. The device of claim 7, wherein when calculating the conversion magnetic field intensity at the target distance, the control unit calculates magnetic field dipole moment based on reference magnetic field intensity stored in advance in a memory which corresponds to the reference distance, and calculates conversion magnetic field intensity at the target distance based on the magnetic field dipole moment.

10. The device of claim 9, wherein when the reference distance is not more than the critical value,
$$m = {H}_{ref} [ \frac{λ {r}^{3}}{\sqrt{{( λ / 2 π )}^{2} + {r}^{2}}} ] [ {Am}^{2} ]$$
and
$${H}_{Mea} = \frac{m}{2 π} [ \frac{\sqrt{{( λ / 2 π )}^{2} + {d}^{2}}}{( λ / 2 π ) {d}^{3}} ] [ A \text{/} m ]$$
when the target distance is not more than the critical value, and
$$m = {H}_{ref} [ \frac{λ {r}^{3}}{\sqrt{{( λ / 2 π )}^{2} + {r}^{2}}} ] [ {Am}^{2} ]$$
and
$${H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A \text{/} m ]$$
when the target distance exceeds the critical value (where m is the magnetic dipole moment, H_{Ref} is the reference magnetic field strength, λ is a wavelength, r is the reference distance, d is the target distance, and H_{Mea} is a conversion magnetic field intensity at the target distance).

11. The device of claim 9, wherein when the reference distance exceeds the critical value,
$$m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ]$$
and
$${H}_{Mea} = \frac{m}{2 π} [ \frac{\sqrt{{( λ / 2 π )}^{2} + {d}^{2}}}{( λ / 2 π ) {d}^{3}} ] [ A \text{/} m ]$$
when the target distance is not more than the critical value, and
$$m = {H}_{Ref} [ \frac{4 {π ( λ / 2 π )}^{2} {r}^{3}}{\sqrt{{( λ / 2 π )}^{4} - {( λ / 2 π )}^{2} {r}^{2} + {r}^{4}}} ] [ {Am}^{2} ]$$
and
$${H}_{Mea} = \frac{m}{4 π} [ \frac{\sqrt{{( λ / 2 π )}^{4} - {( λ / 2 π )}^{2} {d}^{2} + {d}^{4}}}{{( λ / 2 π )}^{2} {d}^{3}} ] [ A \text{/} m ]$$
when the target distance exceeds the critical value (where m is the magnetic dipole moment, H_{Ref} is the reference magnetic field strength, λ is a wavelength, r is the reference distance, d is the target distance, and H_{Mea} is a conversion magnetic field intensity at the target distance).

12. The device of claim 7, wherein the critical value is calculated from 2.354*λ/2π and λ is the wave length.
